(19) United States
(12) Patent Application Publication
(10) Pub. No.: US 2016/0327721 A1
(43) Pub. Date: Nov. 10, 2016

(54) OPTICAL FIBER LIGHTING DEVICE AND METHOD

(71) Applicant: Corning Incorporated, Corning, NY (US)

(72) Inventors: Anthony Sebastian Bauco, Horseheads, NY (US); Joshua Monroe Cobb, Victor, NY (US); Bruce Hildreth Myrick, Keene, NH (US)

(21) Appl. No.: 15/139,900

(22) Filed: Apr. 27, 2016

Related U.S. Application Data
(60) Provisional application No. 62/156,375, filed on May 4, 2015.

(51) Int. Cl. F21V 8/00; H01S 5/022; G02B 27/10; F21K 99/00; G02B 19/00; G02B 27/12

(52) U.S. Cl. CPC G02B 6/0006; G02B 6/001; G02B 19/0014; G02B 19/0057; G02B 27/123; G02B 27/1006; F21K 9/52; H01S 5/02212

(57) ABSTRACT

A lighting device is provided that includes a plurality of laser diodes each producing light in respective beams and a plurality of collimating lenses optically aligned with respective beams of the plurality of laser diodes. The lighting device also includes a field lens optically aligned to receive the laser light emitted by each of the plurality of laser diodes and directed thereto by the plurality of collimating lenses. The lighting device further has a light diffusing fiber having a terminal end located near a focal point of the field lens to receive the laser light, wherein the light diffusing fiber emits light from a side wall.

This application claims the benefit of priority under 35 U.S.C. §119 of U.S. Provisional Application Ser. No. 62/156,375 filed on May 4, 2015 the content of which is relied upon and incorporated herein by reference in its entirety.

### BACKGROUND

This disclosure pertains to a lighting device employing an optical fiber, and more particularly relates to a compact lighting device having a laser diode optically coupled to an optical fiber having a large numerical aperture, such as a light diffusing fiber.

Light diffusing fibers (LDFs) can be used in various applications as light illuminators for accent lighting, indicator lighting and other lighting applications. The overall size of conventional lighting packages is typically large and it can be expensive to efficiently couple light from a diode light source to the optical fiber. It is therefore desirable to provide for a lighting device that illuminates an optical fiber such as a light diffusing fiber with a light package that is compact and economical to produce.

### SUMMARY

In accordance with one embodiment, a lighting device is provided. The lighting device includes a plurality of laser diodes each producing light in respective beams, and a plurality of collimating lenses optically aligned with respective beams of the plurality of laser diodes. The lighting device also includes a field lens optically aligned to receive the laser light emitted by each of the plurality of laser diodes and directed thereto by the plurality of collimating lenses. The lighting device further includes a light diffusing fiber having a terminal end located near a focal point of the field lens to receive the laser light, wherein the light diffusing fiber emits light from a side wall.

In accordance with another embodiment, a lighting device is provided that includes a plurality of laser diodes each producing light emitted in a beam, and a plurality of collimating lenses optically aligned with respective beams of the plurality of laser diodes. The lighting device also includes a field lens optically aligned to receive the laser light emitted by each of the plurality of laser diodes and directed thereto by the plurality of collimating lenses. The lighting device further includes an optical fiber having a terminal end located near a focal point of the field lens to receive the laser light, wherein the optical fiber has a numerical aperture of at least 0.4.

In according with a further embodiment, a method of generating light with a lighting device is provided. The method includes the steps of generating a plurality of laser beams with a plurality of laser diodes, and collimating each of the plurality of laser beams with a plurality of respective collimating lenses. The method also includes the steps of collecting the plurality of laser beams with a field lens and focusing the plurality of collimated laser beams with the field lens onto an end of a light diffusing fiber. The method further includes the step of emitting light resulting from a combination of the plurality of laser beams from the light diffusing fiber.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiments, and together with the description serve to explain principles and operation of the various embodiments.

### BRIEF DESCRIPTION OF THE DRAWINGS

FIG. 1 is a schematic view of a lighting device showing hidden components in phantom, according to one embodiment;

FIG. 2 is an exploded view of the lighting device shown in FIG. 1;

FIG. 3 is a top side view of the lighting device shown in FIG. 1 with the housing cover removed; and

FIG. 4 is a diagrammatic cross-sectional view taken through line Iv-Iv of the lighting diffusing fiber shown in FIG. 3.

### DETAILED DESCRIPTION

Reference will now be made in detail to the present preferred embodiments, examples of which are illustrated in the accompanying drawings. Whenever possible, the same reference numerals will be used throughout the drawings to refer to the same or like parts.

The following detailed description represents embodiments that are intended to provide an overview or framework for understanding the nature and character of the claims. The accompanied drawings are included to provide a further understanding of the claims and constitute a part of the specification. The drawings illustrate various embodiments, and together with the descriptions serve to explain the principles and operations of these embodiments as claimed.

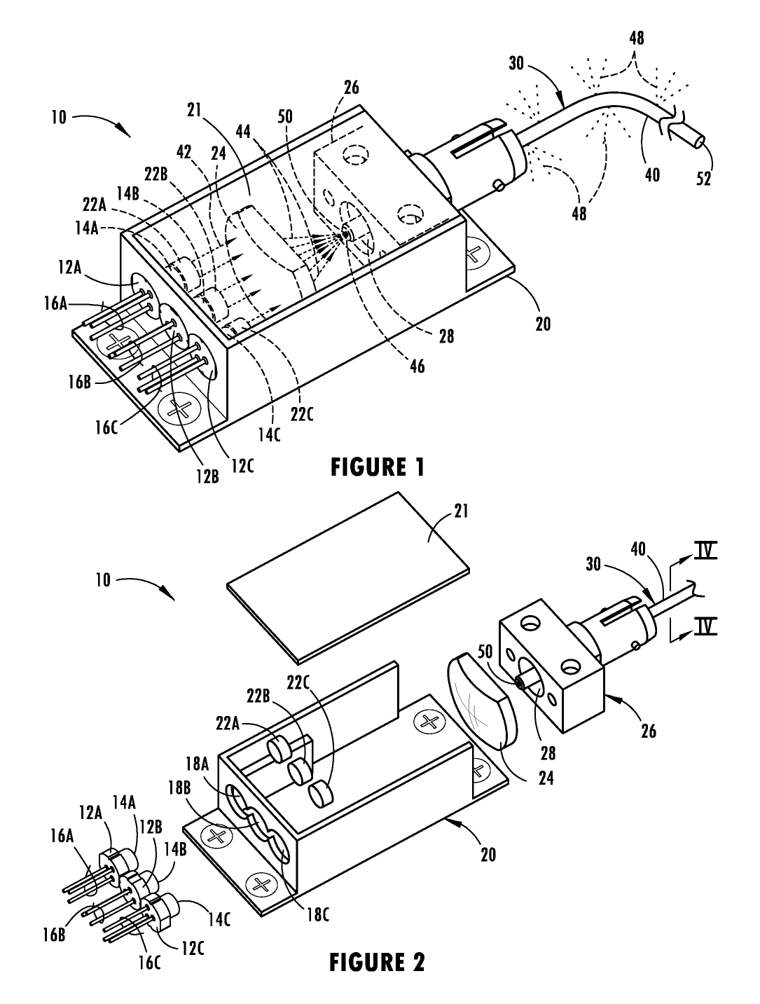

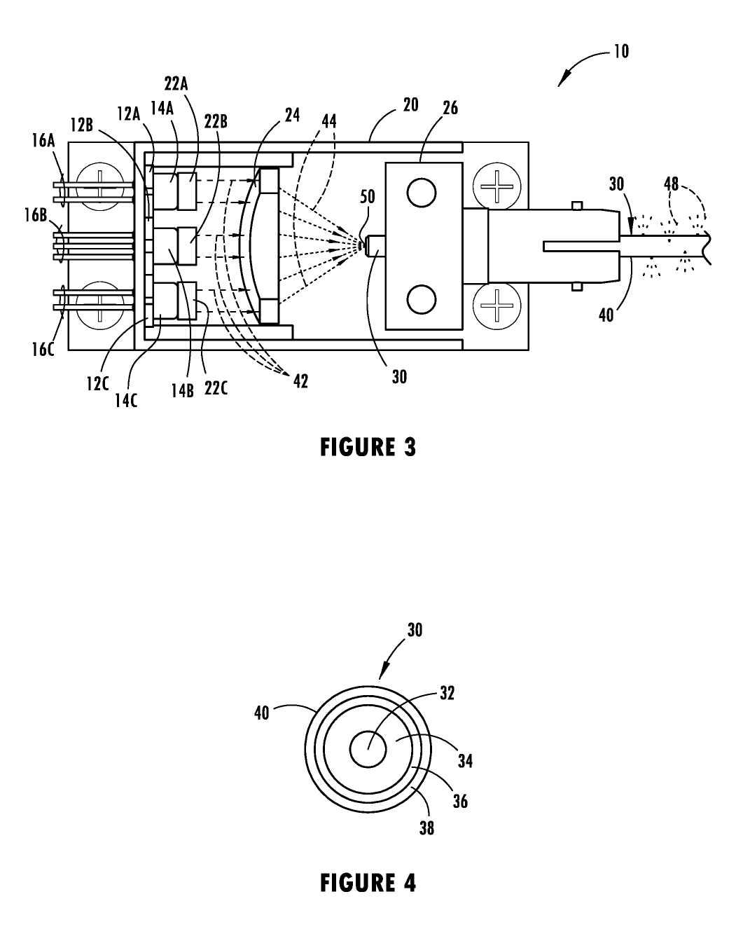

Referring to FIGS. 1-4, a lighting device 10 is illustrated for providing light illumination generated by a plurality of light sources shown generally as three packaged laser diode sources and outputting the light illumination via an optical fiber shown as a light diffusing fiber (LDF) 30, according to one embodiment. The lighting device 10 includes a plurality of light source packages 12A-12C, shown and described herein as three separate laser diode packages, each having a laser diode labelled by identifiers 14A-14C, respectively. In the disclosed embodiment, the three light source packages 12A-12C have respective laser diodes 14A-14C mounted therein and are arranged side-by-side in a linear array. Each of the laser diodes 14A-14C may emit visible light at an emission point and each respective laser beam diverges in an output laser beam path.

In the embodiment shown, there are three laser diodes 14A-14C fixedly connected to a light housing 20 that contains and protects the lighting device components. The housing 20 may be made of a thermal conducting material, such as aluminum. The housing 20 is shown as a rectangular housing generally having a bottom wall, four upstanding side walls, and a top wall or cover 21 that define an enclosure. Other shapes and signal housings may be employed. The bottom wall is shown having mounting plates extending from opposite ends with fasteners (e.g., screws) that enable the housing 20 to be mounted to a device or other structure which may further transfer heat away from the light sources. The light source packages 12A-12C are mounted within generally circular openings 18A-18C, respectively, in one end wall of the light housing 20 such that the laser diodes 14A-14C extend into the enclosure defined by the housing 20. The light source packages 12A-12C may be connected to the housing 20 via a thermally conductive adhesive applied between the openings 18A-18C and the respective light source packages 12A-12C. As such, the thermally conductive housing 20 and the thermally conductive adhesive advantageously conduct thermal energy (heat) away from the light source packages 12A-12C to dissipate thermal energy and prevent overheating.

The lighting device 10 also includes a plurality of collimating lenses 22A-22C mounted in front of the laser diodes 14A-14C and optically aligned with respective beam outputs emitted by the plurality of laser diodes 14A-14C, respectively. The collimating lenses 22A-22C each collimate the laser beam output from a respective one of the laser diodes 14A-14C to generate collimated laser beams 42. The collimating lenses 22A-22C may be configured as molded aspherical glass lenses designed to collimate a laser diode beam and may have a diameter in the range of 2 mm to 5 mm. In the embodiment shown, there are three collimating lenses 22A-22C aligned with the three laser diodes 14A-14C. The collimating lenses 22A-22C may be secured to the light housing 20 via adhesive or other forms of connection. As such, the diverging laser beam output emitted from the first laser diode 14A is captured by the first collimating lens 22A and output as a first collimated laser beam 42 as shown in FIG. 1. Similarly, the diverging laser beam output emitted from the second laser diode 14B is collected and collimated by the second collimating lens 22B and output as a second collimated laser beam 42. Similarly, the diverging laser beam output emitted from the third laser diode 14C is collected and collimated by the third collimating lens 22C and output as a third collimated laser beam 42.

The lighting device 10 further includes an optical field lens 24 aligned to receive the collimated laser light beam 42 emitted by each of the plurality of laser diodes 14A-14C and directed thereto by the plurality of collimating lenses 22A-22C. According to one embodiment, the field lens 24 may include a plano-convex spherical lens. With the linear array of laser diodes, the plano-convex spherical field lens 24 may be truncated on the top and bottom sides to reduce the height at the lens 24 so that it compactly fits within the generally rectangular light housing 20. The plano-convex lens may be truncated to a height of 7 millimeters across the flat of a 10 millimeter diameter lens, according to one example. This allows for the housing assembly height to be reduced from about 12.17 millimeters to 8.85 millimeters, according to this example. The field lens 24 may be an aspherical lens, according to another embodiment. The aspherical field lens 24 may similarly be truncated on top and bottom sides for the linear array of laser diodes. The aspherical lens may have a higher numeral aperture (NA) of about 0.53 which may be used with light diffusing fiber having a similar NA. Truncation of the aspherical lens may reduce it in size. The use of an aspherical lens allows for a shorter focal length. The field lens 24 may be adhered to the light housing 20 or otherwise attached thereto.

The individual collimated laser beams 42 are shown generally extending substantially parallel to one another and each entering a different front side portion of the field lens 24 on the input side. In this embodiment, the plurality of laser beams 42 do not overlap and each beam 42 enters the field lens 24 at separate and distinct locations. The field lens 24 receives each of the collimated laser beams 42 on the input side and focuses the combined laser light beams 42 in a focused converging beam 44 on the output side generally shown as a conical shaped beam that has an impinging point near a bare first terminal end 50 of the optical fiber 30. The field lens 24 has a focal point at which the collected laser beams are combined and focused in a converging beam 44 which is sufficiently focused to a small area near the focal point to direct substantially all of the light collected by the field lens 24 onto the first terminal end 50 and into the optical fiber 30.

The lighting device 10 further includes an optical fiber 30 having the bare first terminal end 50 located near a focal point of the field lens 24 to receive the laser light generated by the laser diodes 14A-14C and collimated and collected by lenses 22A-22C and 24. In one embodiment, the optical fiber 30 is a light diffusing fiber that emits light from a side wall 40 which extends from the first terminal end 50 to a second terminal end 52. The side wall 40 is shown as a cylindrical side wall on the outer surface of the optical fiber 30. It should be appreciated that at least a portion of the light is emitted from the side wall 40. It should further be appreciated that at least some of the light may be emitted from the second terminal end of the optical fiber 30. According to one embodiment, the optical fiber 30 may be a light diffusing fiber such as the commercially available light diffusing fiber manufactured and sold by Corning under the brand name FIBRANCE®.

The optical fiber 30 has a numerical aperture of at least 0.4, and more preferably at least 0.5, and most preferably of about 0.53. In one embodiment, the optical fiber 30 is a light diffusing fiber with a numerical aperture of at least 0.3, or at least 0.4, or at least 0.5, or at least 0.6, or at least 0.7, or about 0.53. The optical fiber 30 may have a diameter in the range of 50 μm to 200 μm. The optical fiber 30 is shown fixedly connected to a connector 26 which, in turn, is connected to the light housing 20. The connector 26 holds the bare first terminal end 50 of the optical fiber 30 in a fixed position to receive the light focused thereon by the field lens 24. The connector 26 is shown including a block that fits within the housing 20 and may be fixedly attached thereto to hold the optical fiber 30 in a desired position and orientation relative to the focal point of the field lens 24. The fiber connector 26 may include an ST-type connector, according to one embodiment. Accordingly to other embodiments, the fiber connector 26 may include an FC or SMA receptacle. Alternatively, the optical fiber 30 can be mounted in a ferrule and bonded into a fixed location.

While a plurality of laser diodes 14A-14C are shown arranged in a linear array according to one embodiment, it should be appreciated that the plurality of laser diodes 14A-14C may otherwise be oriented. For example, the plurality of laser diodes may be oriented in a triangular or circular pattern, which may be centered about the central optical axis. If a greater number of wavelengths of light are required, additional laser sources may be employed. If greater laser power is required, a plurality of lasers having the same wavelength may be employed to provide for enhanced power output for a given output power of the laser diodes. It is also possible to use multiple lasers of the same wavelength combined with other lasers of other wavelengths may be employed.

The light source packages 12A-12C may include a laser source package in the form of a TO can package. Three commercially available TO can packages may be inserted within openings 18A-18C and connected to the housing 20 in optical alignment with the collimating lenses 22A-22C. The light source packages 12A-12C each have a diode housing and a plurality of input pins 16A-16C. The TO can package housing may include a metal can and the diodes 14A-14C may be disposed within the diode housing and sealed therein. The laser diodes 14A-14C each receive electrical power via the input pins 16A-16C and generate a laser light emission at an emission point that diverges in the output laser beam. Each laser diode 14A-14C may generate a particular wavelength for a specific colored light, such as red, green or blue at certain wavelengths within the laser light spectrum. In one embodiment, the first laser diode 14A generates a green laser beam at a first wavelength, the second laser diode 14B generates a red laser beam at a second wavelength, and the third laser diode 14C generates a blue laser beam at a third wavelength. By employing red, green and blue laser diodes in various combinations and proportions, a plurality of different color light outputs may be generated for illumination from the light diffusing fiber 30. The color or hue of the light that may be generated and output by the light diffusing fiber 30 may be produced by controlling the pulse width modulation (PWM) or intensity of each of the red, green and blue laser diodes 14A-14C so as to adjust the proportion of each color laser beam.

The light source packages 12A-12C are arranged close together within the housing 20 and may include truncations on the housing of each package to position the diodes 14A-14C as close together as possible. Green and blue laser diodes may be employed on the ends of the linear array as laser diodes 14A and 14C, and a red laser diode may be positioned in the center as diode 14B. Since the red diode emits less heat compared to the green and blue diodes, less thermal energy is generated centrally within the housing. It should be appreciated that the light source packages 12A-12C may be mounted to the housing 20 and thereafter the optical lenses 22A-22C and 24 may be aligned with the laser diodes 14A-14C and fixed in place during assembly.

The lighting device 10 may be used as a standalone lighting device. The light source packages 12A-12C each have a compact size with height and length dimensions sufficiently small to enable use in compact applications including use in small devices and applications such as consumer electronics (e.g., cell phone). The light source packages 12A-12C may include a commercially available TO can package which is available with a glass window aligned with the light outlet. Examples of a TO can package include commercially available 3.3 mm and a 3.8 mm TO can packages.

The light diffusing fiber 30 may be of any suitable length to provide sufficient illumination for a given application. In one embodiment, the light diffusing fiber 30 has a length up to at least 10 meters. Exhanced length of the light diffusing fiber 30 and/or enhanced light output may be achieved by coupling a light housing 20 at opposite ends 50 and 52 of the light diffusing fiber 30. The fiber 30 may be connected to the connector 26 which in turn is connected to housing 20. The first terminal end 50 of the fiber 30 is preferably very smooth such that when aligned with the field lens 24, the laser light combined from the three collected laser output beams is efficiently emitted into the light diffusing fiber 30 at the first terminal end 50.

The lighting device 10 may be used as a standalone lighting device or may be assembled into a device such as a consumer electronics device or employed in another application to provide a compact and inexpensive lighting device. It should be appreciated that the light diffusing fiber 30 may have various shapes and sizes to accommodate dimensions of the device and lighting application.

In one embodiment, the lighting device 10 includes a light diffusing fiber 30 operatively coupled to the plurality of laser diodes 14A-14C via lenses 22A-22C and 24 to receive substantially all of the light generated by the laser diodes 14A-14C and disperses the light 48 from a side wall 40 of the light diffusing fiber 30 for a lighting application. The light diffusing fiber 30 is a high scatter light transmission fiber that receives the combined laser light and scatters and outputs the light from the side wall 40. The high scatter light transmission achieved with the light diffusing fiber 30 has a light attenuation of 0.5 dB/meter or greater, according to one embodiment.

The light diffusing fiber 30 may be configured as a single light diffusing fiber. The light diffusing fiber 30 may be a multimode fiber having a diameter, for example, in the range of 50 to 200 micrometers and may be flexible, thus allowing ease in installation to the connector 26 which, in turn, is connected to housing 20. In one embodiment, the light diffusing fiber 30 has a diameter of 1,000 microns or less, and more particularly of about 250 microns or less. In other embodiments, the light diffusing fiber 30 may be more rigid and have a diameter greater than 1,000 microns.

One embodiment of a light diffusing fiber 30 is illustrated having a typical cross-sectional structure as shown in FIG. 4. The light diffusing fiber 30 may include the formation of random air lines or voids in one of the core and cladding of a silica fiber. Examples of techniques for designing and forming such light diffusing fibers may be found, for example, in U.S. Pat. Nos. 7,450,806; 7,930,904; and 7,505,660, and U.S. Patent Application Publication No. 2011/0305035, which are hereby incorporated by reference in their entirety. The light diffusing fiber 30 has a SiO₂ glass core 32 which may include a Ge-doped or F-doped core. The glass core has a diameter greater than 20 microns, according to one embodiment. An SiO₂ cladding layer 34 having air lines for scattering light is shown surrounding the core 32. The cladding layer 34 may be formed to include air lines or voids to scatter the light and direct the light through the side wall 40. It should be appreciated that the random air lines may be disposed in the core 32 or in the cladding 34 or in both, according to various embodiments. It should be appreciated that high scattering light losses are generally preferred in the light diffusing fiber 30. A low index polymer primary protective layer 36 generally surrounds the cladding layer 34. Additionally, an outer secondary layer 38 may be disposed on the primary protective layer 36. Primary protective layer 36 may be soft (low modulus), while secondary layer 38 may be harder (high modulus).

Scattering loss of the light diffusing fiber 30 may be controlled throughout steps of fiber manufacture and processing. During the air line formation process, the formation of a greater number of bubbles will generally create a larger amount of light scatter, and during the draw process the scattering can be controlled by using high or low tension to create higher or lower light loss, respectively. To maximize loss of light, a polymeric cladding may be removed as well, over at least a portion of the light diffusing fiber 30 length if not all. Uniform angular loss in both the direction of light propagation, as well as in the reverse direction can be made to occur by coating the light diffusing fiber 30 with inks that contain scattering pigments or molecules, such as TiO₂. The high scattering light diffusing fiber 30 may have a modified cladding to promote scattering and uniformity. Intentionally introduced surface defects on the light diffusing fiber 30 outside surface or its core or cladding may also be added to increase light output, if desired.

The light diffusing fiber 30 may have a region or area with a large number (greater than 50) of gas filled voids or other nano-sized structures, e.g., more than 50, more than 100, or more than 200 voids in the cross section of the fiber. The gas filled voids may contain, for example, SO₂, Kr, Ar, CO₂, N₂, O₂ or mixture thereof. The cross-sectional size (e.g., diameter) of the nano-size structures (e.g., voids) may vary from 10 nanometers to 1 micrometer (for example, 15 nanometers to 500 nanometers), and the length may vary depending on the area to be illuminated.

While the light diffusing fiber 30 is shown and described herein having air lines, it should be appreciated that other light scattering features may be employed. For example, high index materials such as GeO₂, TiO₂, ZrO₂, ZnO, and others may be employed to provide high scatter light transmission.

According to other embodiments, the lighting device 10 uses a low scatter light transmission fiber, referred to as light delivery fiber. In this embodiment, the optical fiber has a numerical aperture of at least 0.4, more preferably at least 0.5, and most preferably about 0.53. The light delivery fiber may have a numerical aperture of at least 0.3, or at least 0.4, or at least 0.5, or at least 0.6, or at least 0.7, or about 0.53. The lighting device 10 may utilize the light delivery fiber to deliver the light to be emitted from the second terminal end 52 or to transfer the light to another device. Alternatively, the light delivery fiber may be coupled at the second terminal end 52 to a light diffusing fiber, which in turn emits the light from a side wall. The delivery fiber may include an optical fiber designed to transmit light with low signal loss. The low scatter light transmission achieved with the delivery fiber has a light attenuation of less than 0.5 dB/meter.

Accordingly, the lighting device 10 advantageously couples light from a plurality of laser diodes, such as those present in TO can packages, to a light diffusing fiber to provide light illumination. The lighting device 10 may employ an existing TO can package which is compact and economical to manufacture. The lighting device 10 has sufficiently small dimensions including width, height and length such that it may be advantageously employed in any of a number of applications.

Various modifications and alterations may be made to the examples within the scope of the claims, and aspects of the different examples may be combined in different ways to achieve further examples. Accordingly, the true scope of the claims is to be understood from the entirety of the present disclosure in view of, but not limited to, the embodiments described herein.

It will be apparent to those skilled in the art that various modifications and variations can be made without departing from the spirit or scope of the claims.

What is claimed is:

1. A lighting device comprising:
a plurality of laser diodes, each laser diode of the plurality producing a beam of laser light;
a plurality of collimating lenses for receiving the laser light beams, the plurality of collimating lenses including a collimating lens optically aligned with each of the laser light beams;
a field lens optically aligned with the plurality of collimating lenses to receive the laser light beams from the plurality of collimating lenses; and
a light diffusing fiber having a terminal end located near a focal point of the field lens to receive the laser light beams from the field lens, the light diffusing fiber having a side wall and scattering light from the laser light beams through the side wall.

2. The lighting device of claim 1, wherein the light diffusing fiber has a numerical aperture of at least 0.4.

3. The lighting device of claim 1, wherein the light diffusing fiber has a numerical aperture of at least 0.5.

4. The lighting device of claim 1, wherein the plurality of laser diodes comprises a first laser diode producing a first color laser light beam and a second laser diode producing a second color laser light beam.

5. The lighting device of claim 4 further comprising a third laser diode producing a third color laser light beam.

6. The lighting device of claim 1, wherein the plurality of collimating lenses are aspherical lenses and the field lens is one of an aspherical lens and a plano-convex lens.

7. The lighting device of claim 1, wherein the light diffusing fiber is a multimode fiber.

8. The lighting device of claim 1, wherein the light diffusing fiber comprises a core having a diameter greater than 20 microns.

9. The lighting device of claim 1, wherein each of the plurality of laser diodes is provided in a TO can laser source package.

10. A lighting device comprising:
a plurality of laser diodes, each of the plurality producing a beam of laser light;
a plurality of collimating lenses for receiving the laser light beams, the plurality of collimating lenses including a collimating lens optically aligned with each of the laser light beams;
a field lens optically aligned with the plurality of collimating lenses to receive the laser light beams from the plurality of collimating lenses; and
an optical fiber having a terminal end located near a focal point of the field lens to receive the laser light beams from the field lens, the optical fiber having a numerical aperture of at least 0.4.

11. The lighting device of claim 10, wherein the optical fiber has a numerical aperture of at least 0.5.

12. The lighting device of claim 10, wherein the optical fiber comprises a light diffusing fiber having a side wall, the light diffusing fiber scattering light from the laser light beams through the side wall.

13. The lighting device of claim 10, wherein the plurality of laser diodes comprises a first laser diode producing a first color laser light beam and a second laser diode producing a second color laser light beam.

14. The lighting device of claim 13 further comprising a third laser diode producing a third color laser light beam.

15. The lighting device of claim 12, wherein the light diffusing fiber is a multimode fiber.

16. The lighting device of claim 10, wherein the plurality of collimating lenses are aspherical lenses and the field lens is one of an aspherical lens and a plano-convex lens.

17. The lighting device of claim 10, wherein each of the plurality of laser diodes is provided in a TO can laser source package.

18. A method of generating light with a lighting device, the method comprising the steps of:
generating a plurality of laser light beams with a plurality of laser diodes;
collimating each of the plurality of laser light beams with a plurality of respective collimating lenses;
collecting the plurality of laser light beams with a field lens;
focusing the plurality of collimated laser light beams with the field lens onto an end of a light diffusing fiber; and
scattering light from the focused laser light beams through a side wall of the light diffusing fiber.

19. The method of claim 18, wherein the light diffusing fiber has a numerical aperture of at least 0.4.

20. The method of claim 18, wherein the plurality of laser diodes generates laser light beams having a plurality of different colors, the method further comprising adjusting a proportion of each of the laser light beams and combining the adjusted laser light beams to select a color of the scattered light.

21. The lighting device of claim 1, wherein the collimated laser light beams received by the field lens are non-overlapping.

22. The lighting device of claim 10, wherein the collimated laser light beams received by the field lens are non-overlapping.

23. The lighting device of claim 10, wherein the optical fiber comprises a light delivery fiber.

24. The lighting device of claim 23, wherein the optical fiber further comprises a light diffusing fiber optically coupled to the light delivery fiber.

25. The lighting device of claim 1, wherein the laser light beams received by the terminal end of the light diffusing fiber are non-overlapping.

26. The lighting device of claim 10, wherein the laser light beams received by the terminal end of the optical fiber are non-overlapping.

27. The lighting device of claim 5, wherein the first color laser beam is a red laser beam, the second color laser beam is a green laser beam, and the third color laser beam is a blue laser beam.

28. The lighting device of claim 27, wherein the first laser diode, the second laser diode, and the third laser diode are arranged as a linear array and wherein the first laser diode is positioned between the second laser diode and the third laser diode in the linear array.

29. The lighting device of claim 14, wherein the first color laser beam is a red laser beam, the second color laser beam is a green laser beam, and the third color laser beam is a blue laser beam.

30. The lighting device of claim 29, wherein the first laser diode, the second laser diode, and the third laser diode are arranged as a linear array and wherein the first laser diode is positioned between the second laser diode and the third laser diode in the linear array.

31. The lighting device of claim 1, wherein the light diffusing fiber has a diameter in the range of 50 to 200 micrometers.
